(19) United States
(12) Patent Application Publication
(10) Pub. No.: US 2013/0162959 A1
(43) Pub. Date: Jun. 27, 2013

(54) Brightness-adjustable Light-emitting Device and Array and the Manufacturing Methods Thereof

(71) Applicants: Pengfei Wang, Shanghai (CN); Xi Lin, Shanghai (CN); Xinyan Xiu, Shanghai (CN); Wei Zhang, Shanghai (CN)

(72) Inventors: Pengfei Wang, Shanghai (CN); Xi Lin, Shanghai (CN); Xinyan Xiu, Shanghai (CN); Wei Zhang, Shanghai (CN)

(73) Assignee: FUDAN UNIVERSITY, Shanghai (CN)

(21) Appl. No.: 13/498,146

(22) PCT Filed: Nov. 15, 2011
(86) PCT No.: PCT/CN11/01908

§ 371 Date: Mar. 12, 2013

(30) Foreign Application Priority Data
Nov. 16, 2010 (CN) 201010545127.3

(51) Int. Cl. H01L 27/15; G03B 21/14; H01L 33/06

(52) U.S. Cl. 353/85; 438/23; 257/13; 257/E27.121; 257/E33.008

(57) ABSTRACT

The present invention belongs to the technical field of semiconductor devices and relates to a brightness-adjustable illuminator and an array and the manufacturing methods thereof. The illuminator is comprised of a semiconductor substrate, a MOSFET and a light-emitting diode that are located on the semiconductor substrate. The light-emitting diode (LED) and the control element (MOSFET) thereof are integrated on the same chip, so a single chip is capable of realizing the image transmission. An illuminator array may consist of a plurality of illuminators. Meanwhile, the invention also discloses a method for manufacturing the illuminator. Therefore, the projection equipment manufactured by the technology of the present invention has the advantages of small size, portability, low power consumption, etc. Furthermore, the use of the integrated circuit chip greatly simplifies the system of the projection equipment, reduces the production cost and greatly enhances the pixel quality and brightness.

### TECHNICAL FIELD

The present invention belongs to the technical field of semiconductor devices and relates to a semiconductor device and a manufacturing method thereof, in particular to a brightness-adjustable illuminator and an array and the manufacturing methods thereof.

### BACKGROUND TECHNOLOGY

A projector is a projection device for amplifying and displaying images. At present, projectors have been used for presentation in meeting rooms and for watching movies on a large screen at home by connecting equipment such as DVD players. Cinemas have also started substituting old filmstrips for digital cinema projectors, which are used as hard disk digital data-oriented silver screens. According to different working principles, the projectors are capable of being classified into three types: CRT, LCD and DLP, wherein CRT projects are on the verge of elimination, LCD projectors, also known as liquid crystal display projectors, hold the mainstay and DLP projectors also hold a certain share.

LCD projectors are driven to emit light to form images, and the core unit thereof is the LCD panel. The mainstream LED projector adopts three LED panels. See FIG. 1a for the imaging principle and the imaging process thereof. First, the white light emitted from a bulb passes through a light filter to remove invisible light, such as infrared rays and ultraviolet rays, and the filtered light is sent to a bicolor mirror by a reflector and a condenser. Second, the red light is firstly separated out and then projected on a red liquid crystal display panel by the reflector and the condenser, wherein the image information represented by the transparency “recorded” on the liquid crystal display panel is projected and formed into the red light information in the image. In the same way, the green light and the blue light are separated out in sequence and then respectively projected to the perspective liquid crystal display panel via the reflector and the condenser to generate the green light information and the blue light information. Finally, the red light, green light and blue light are converged in a converging prism and projected onto a screen by a projection lens to form a full color image.

The DLP projector technology is a fully digital reflection projection technology, and the core unit thereof is a DMD (Digital-Micromirror-Device) chip. See FIG. 1b for the imaging principle and imaging process of the DLP projector. At first, the white light emitted from the bulb passes through a tricolor lens (color wheel) that is rotating at a high speed to separate and process the red light, green light and blue light, and then the three types of light rays are projected onto the DMD chip; the chip, consisting of hundreds of thousands of micromirrors, switches the optical pixels at a high speed to generate projection images, and finally, the projection images of the red, green and blue light are projected onto the screen by an optical lens to form the image projection. The shaking of the micromirrors and the high rotation speed of the color wheel cause a visual illusion to human, where the human eyes mix up the red, green and blue light that flash quickly to see the mixed colors on the projected image.

Both LCD projectors and the DLP projectors use the same light source, and the LED filters the light source or the micromirrors adjust the reflection angle for the light source to form the image, while the integrated light source and the control element chip thereof are not used. At present, the projector for which the light source and control element are separated is large in size, not portable and has high power consumption.

### DESCRIPTION OF THIS DISCLOSURE

The present invention aims to provide a novel brightness-adjustable semiconductor device and a chip. The projector manufactured from the semiconductor device and the chip has the advantages of small size, portability, convenient use, low power consumption, etc.

To fulfill the abovementioned aim, the present invention provides a brightness-adjustable illuminator comprising a semiconductor substrate, a metal-oxide-semiconductor field effect transistor (MOSFET) and a light-emitting diode (LED) formed on the semiconductor substrate, wherein:

the LED is comprised of a luminous layer, a p-type region located above the luminous layer and an n-type region located below the luminous layer;

the MOSFET is comprised of a silicon substrate, a gate region located on the silicon substrate, and a source region and drain region that are located in the silicon substrate and on the two sides of the gate region;

the silicon substrate of the MOSFET is isolated from the LED and the semiconductor substrate by a partition; and

the source region of the MOSFET and the p-type region of the LED are connected by a metal, and the MOSFET controls the LED to emit light from the metal.

Furthermore, the semiconductor substrate is a semiconductor selected from the III-V family, such as GaN, GaP, GaAs, InGaAs, InP, SiC, etc. The luminous layer of the LED is a single quantum well structure or multiple quantum well structures consisting of materials such as AlGaAs, InGaAsP, GaP, GaAsP, AlGaInP, InGaN, GaN, SiC.

Furthermore, the invention provides an array consisting of a plurality of brightness-adjustable illuminators, wherein the drain of each MOSFET is connected with one of the bit lines in the array, the gate of each MOSFET is connected with one of the word lines in the array and the cathode of each LED is connected with one of the ground lines in the array.

Meanwhile, the invention also provides a method for manufacturing the brightness-adjustable illuminator, comprising:

providing a semiconductor substrate;

processing a vertical LED structure on the semiconductor substrate, wherein the LED structure is comprised of a p-type region, a luminous layer and an n-type region of an LED from the top down;

forming a first insulation film on the p-type region of the LED;

providing a second semiconductor substrate and forming a silicon oxide film on the surface of the second semiconductor substrate;

bonding the first insulation film and the silicon oxide film on the surface of the second semiconductor substrate;

processing a MOSFET structure on the surface of the other side of the second semiconductor substrate that is not bonded, wherein the MOSFET structure is comprised of a source region, a drain region and a gate region located above a groove between the source region and the drain region;

forming a second insulation film on the gate region between the source region and the drain region and etching the second insulation film to form contact holes; and

forming a first conductive film in the contact holes and above the second insulation film and etching the first conductive film to form metal contact, wherein the p-type region of the LED and the source region of the MOSFET are connected via the first conductive film.

Furthermore, the first and second insulation films are SiO₂ or Si₃N₄ films. The first conductive film is made of conductive metallic materials, such as Cu, Al, TiN, Ti, Ta, TaN or others.

In the brightness-adjustable illuminator provided by the present invention, the semiconductor selected from the III-V family, such as GaN, GaP, GaAs, InGaAs, InP, SIC, etc., is used as the substrate, and the LED and control element, namely MOSFET, are integrated in the same chip, so a single chip can realize image transmission. Therefore, the projection equipment manufactured by the technology of the present invention has the advantages of small size, portability, low power consumption, etc. Furthermore, the use of the integrated circuit chip greatly simplifies the system of the projection equipment, reduces the production cost and greatly enhances the pixel quality and brightness. The brightness-adjustable illuminator provided in the present invention is very suitable for manufacturing the integrated circuit chip, especially for manufacturing low-consumption, moveable projection equipment.

### BRIEF DESCRIPTION OF THE ATTACHED DRAWINGS

FIG. 1a is an internal functional graph of an LED projector in the prior art.

FIG. 1b is an internal functional graph of an LED projector in the prior art.

FIG. 2a is a sectional view of one embodiment of the brightness-adjustable illuminator provided by the present invention.

FIG. 2b is a top view of the illuminator as shown in FIG. 2a.

FIG. 2c is an equivalent circuit diagram of the illuminator as shown in FIG. 2a.

FIG. 3a is a top view of one embodiment of an illuminator array consisting of a plurality of illuminators as shown in FIG. 2a.

FIG. 3a is an equivalent circuit diagram of an illuminator array consisting of a plurality of illuminators as shown in FIG. 2a.

FIGS. 4a to 4f show the process flowcharts for manufacturing the illuminator device as shown in FIG. 2a.

FIG. 5 is an equivalent circuit diagram of an illuminator array capable of generating three primary lights.

FIG. 6 is a schematic view of a projector manufactured by adopting the technology provided by the present invention.

### OPTIMAL EMBODIMENT OF THIS INVENTION

The embodiment of the present invention is further described in detail by means of the attached drawings. In the figure, to facilitate description, the layer thickness and region thickness are amplified, but the sizes do not represent the actual dimensions. The reference is a schematic view of an ideal embodiment. The embodiment of the present invention shall not be limited to the specific shapes of the regions as shown in the figure but comprise obtained shapes, including such deviations caused by manufacturing. For example, an etched curve is usually characterized as a bend or roundness and smoothness. In this embodiment, however, all curves are represented by rectangles. The figure is schematic and shall not be considered as limit of the present invention. Meanwhile, in the below description, the term “substrate” may be considered to comprise a semiconductor wafer being processed or other films prepared on the semiconductor wafer.

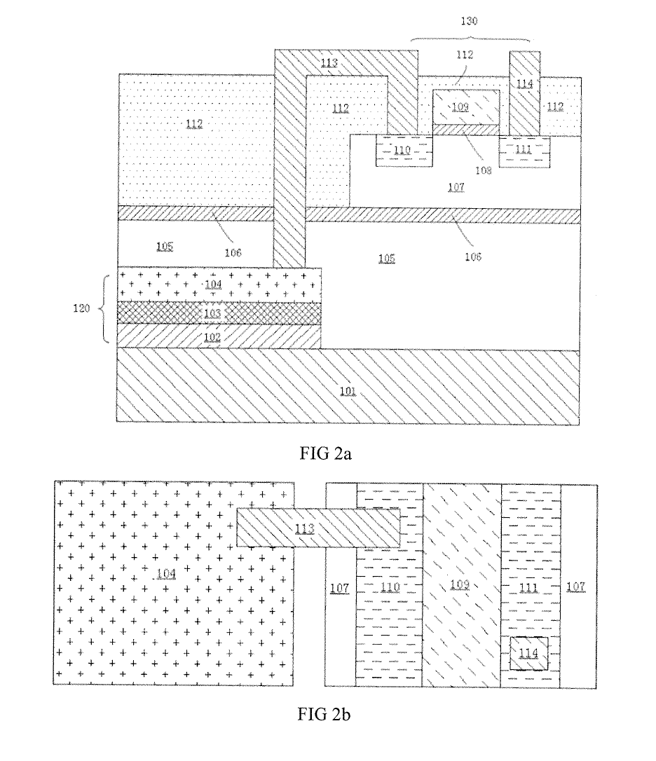

FIG. 2a is a sectional view along the length direction of the groove of the illuminator according to an embodiment of a brightness-adjustable illuminator provided by the present invention; FIG. 2b is a top view of the illuminator as shown in FIG. 2a. As shown in FIGS. 2a and 2b, the illuminator is comprised of a semiconductor substrate 101, a MOSFET 130 and LED 120 formed on the substrate 101. The semiconductor substrate is a semiconductor selected from the III-V family, such as GaN, GaP, GaAs, InGaAs, InP, SiC, etc. The MOSFET 130 is isolated from the LED 120 and the substrate 101 via thick oxide layers 105. The LED 120 is comprised of an n-type region 102, a luminous layer 103 and a p-type region 104, and the luminous layer 103 is a single or multimple quantum well structure consisting of materials such as AlGaAs, InGaAsP, GaP, GaAsP, AlGaInP, InGaN, GaN, or SiC. The MOSFET 130 is formed on the silicon (SOI) layer of the insulator, consisting of a thick oxide layer 105, a thin oxide layer 106 and a silicon layer 107 and comprised of a source region 110, a drain region 111 and a gate region, consisting of a gate dielectric layer 108 and a gate electrode 109. A gate dielectric layer 108 is made of SiO₂, and the gate electrode 109 is made of such metal materials as TiN, TaN, RuO₂, Ru, WSi, etc., or doped with a polycrystalline material. A metal layer 114 contacts the drain, and a metal layer 113 is connected with the source region 110 of the MOSFET and the p-type region 104 of the LED. An insulating layer 112 is a passivation layer of the device, isolating the device from other devices and protecting the device from the influence of the outside environment.

See FIG. 2c for the equivalent diagram of the brightness-adjustable illuminator at work as shown in FIG. 2a. The cathode terminal of the LED is connected with the low level GND, the word line (WL) controls the gate electrode of the MOSFET, the bit line (BL) controls the drain of the MOSFET and the WL and BL together control the make-and-break of the MOSFET and the LED lighting.

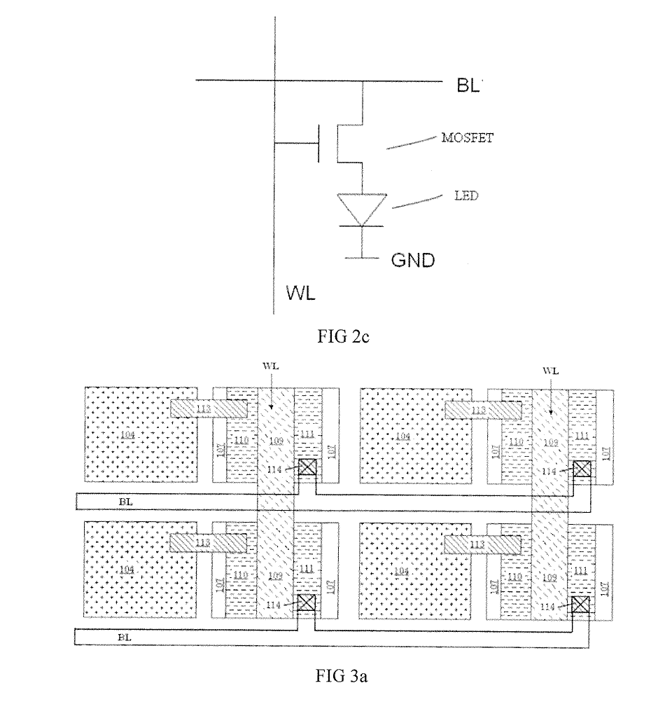

FIG. 3a is a top view of an illuminator array consisting of a plurality of brightness-adjustable illuminators as shown in FIG. 2a, and FIG. 3b is an equivalent diagram of the illuminator array at work as show in FIG. 3a. As shown in FIGS. 3a and 3b, the drain of the MOSFET and the gate of the MOSFET are connected with any one of the BLs in the array, respectively, and the cathode of the LED in the array is grounded.

The brightness-adjustable illuminator disclosed in the present invention is capable of being manufactured by many methods. The following contains the processing procedures of one embodiment of the manufacturing the brightness-adjustable illuminator as shown in FIG. 2a.

Although the drawings fail to completely reflect the real dimensions exactly, they still completely show the relative positions of the regions and the components, especially in the vertical and neighbor relations of the components.

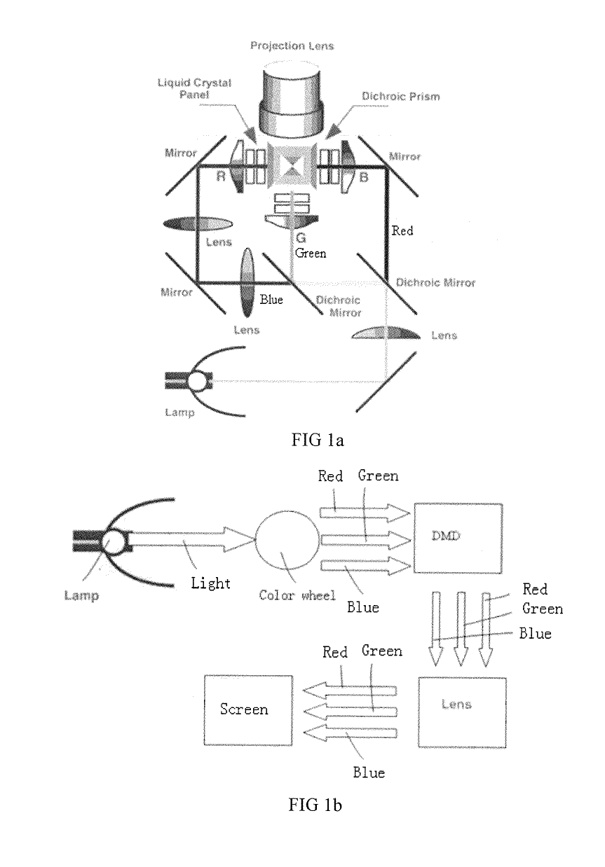

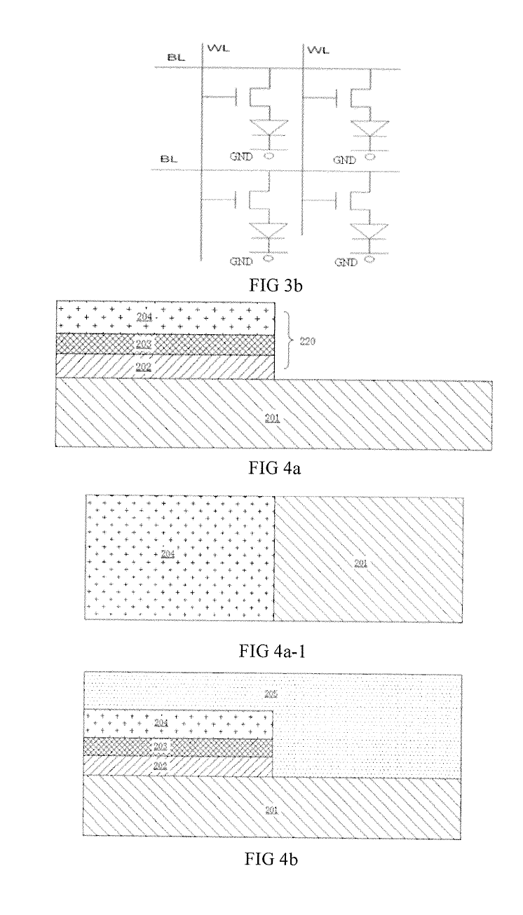

First, process the LED structure 220 of the device on the provided semiconductor substrate 201 by epitaxial process (preferably MOCVD) and etching process, wherein the LED 220 is comprised of an n-type region 202, a luminous layer 203 and a p-type region 204. In the embodiment of the present invention, if the manufacturing process of the brightness-adjustable illuminator is intended for blue LEDs, then the semiconductor substrate 201 is selected from a GaN material, and the luminous layer 203 is a single or multiple quantum well structure made from the InGaN/GaN material. FIG. 4a-1 is a top view of the structure as shown in FIG. 4a.

Second, deposit a thick passivation layer 205, for example silica, and then flatten the passivation layer, as shown in FIG. 4b.

Next, bond a silica oxide layer 205 with the upside down silicon wafer 207, wherein the surface of the silicon wafer 207 is oxidized and grows a thin silicon dioxide layer 206; therefore, the thick silica layer 205, the thin silicon dioxide layer 206 and the silicon wafer 207 form the silicon (SOI) layer on the insulator, as shown in the FIG. 4c.

Third, grow a thin silicon dioxide layer 208 on the surface of the silicon wafer 207, deposit a conductive material layer 209 and a photoresistor layer in turn, perform masking, exposing and etching to form the gate region 230 of the MOSFET and then remove the photoresistor, as shown in FIG. 4d. The conductive material layer 209 may be comprised of metal materials such as TIN, TaN, RuO₂, Ru, WSi, etc., or doped with a polycrystalline material.

Fourth, deposit a photoresistor layer 210, perform masking, exposing and etching to form a pattern in which the source region and drain region of the MOSFET are doped and then carry out ion injection to form the resource region 211 and the drain region 212 of the MOSFET, as shown in FIG. 4e.

Remove the photoresistor 210, deposit an insulation dielectric layer 213 and a photoresistor layer, perform masking, exposing and etching to form a contact hole, remove the rest photoresistor layer, deposit a layer of metal 214 and etch the metal to form metallic contact, as shown in FIG. 4f.

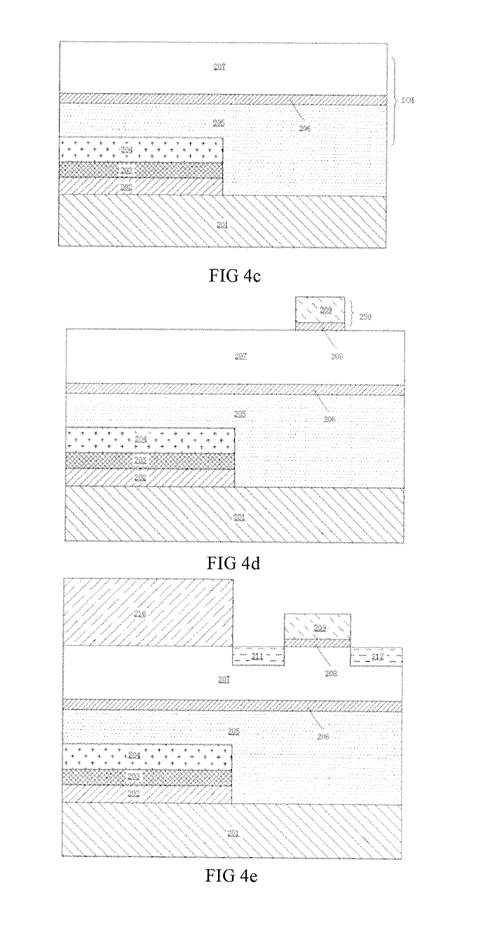

Furthermore, if the illuminators that are manufactured by the technology of the present invention and are capable of generating different colors are combined together, e.g. the illuminators generating red, blue and green light are combined together (see FIG. 5 for the equivalent diagram), the full-color display can be realized by adjusting the intensity of the red, blue and green light.

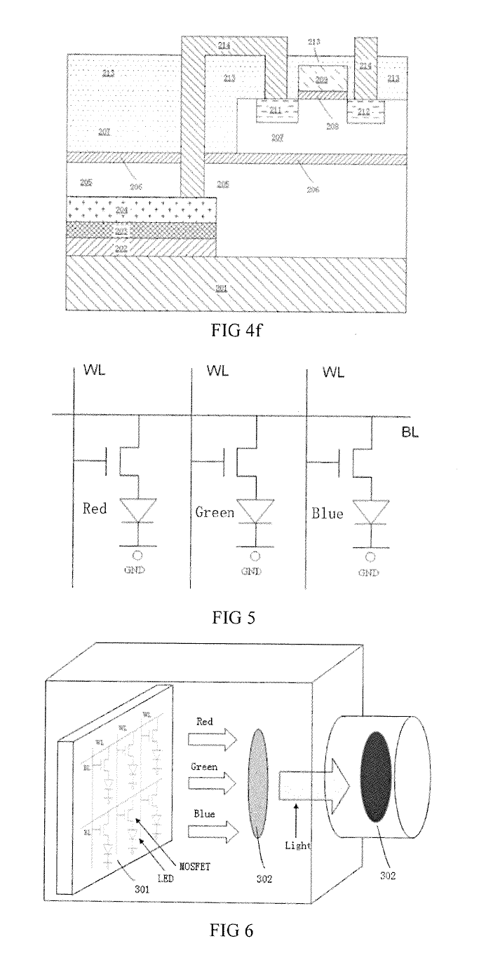

FIG. 6 is a schematic view of a projector manufactured by the technology of the present invention. As shown in FIG. 5, 301 represents the chip in which the LED and the control element (MOSFET) are integrated, 302 represents a converging lens and 303 represents a projection lens.

### INDUSTRIAL APPLICATION

In the brightness-adjustable illuminator provided by the present invention, the semiconductor selected from the III-V family, such as GaN, GaP, GaAs, InGaAs, InP, SiC, etc., is used as the substrate, and the LED and the control element, namely MOSFET, are integrated in the same chip, so a single chip can realize image transmission. Therefore, the projection equipment manufactured by the technology of the present invention has the advantages of small size, portability, low power consumption, etc. Furthermore, the use of the integrated circuit chip greatly simplifies the system of the projection equipment, reduces the production cost and greatly enhances the pixel quality and brightness. The brightness-adjustable illuminator provided in the present invention is very suitable for manufacturing integrated circuit chips, especially in manufacturing low-consumption, moveable projection equipment.

As mentioned above, under the condition of being within the spirit and scope of the present invention, there may be many embodiments with a variety of differences. It should be understood that, except where so claimed, the present invention is not limited to the embodiments described in the description.

1. A brightness-adjustable illuminator comprising a semiconductor substrate, a metal-oxide-semiconductor field effect transistor (MOSFET) and a light-emitting diode (LED) formed on the semiconductor substrate, wherein:
the LED is comprised of a luminous layer, a p-type region located above the luminous layer and an n-type region located below the luminous layer;
the MOSFET is comprised of a silicon substrate, a gate region located on the silicon substrate, and a source region and drain region that are located in the silicon substrate and on the two sides of the gate region;
the silicon substrate of the MOSFET is isolated from the LED and the semiconductor substrate by a partition; and
the source region of the MOSFET and the p-type region of the LED are connected by a metal, and the MOSFET controls the LED to emit light from the metal.

2. The brightness-adjustable illuminator of claim 1, wherein, the semiconductor substrate is a semiconductor selected from GaN, GaP, GaAs, InGaAs, InP, or SiC.

3. The brightness-adjustable illuminator of claim 1-2, wherein, the luminous layer of the LED is a single quantum well structure or multiple quantum well structures consisting of materials such as AlGaAs, InGaAsP, GaP, GaAsP, AlGaInP, InGaN, GaN, or SiC.

4. An array consisting of a plurality of brightness-adjustable illuminators of claim 1, wherein the drain of each MOSFET is connected with one of the bit lines in the array, the gate of each MOSFET is connected with one of the word lines in the array and the cathode of each LED is connected with one of the ground lines in the array.

5. A method for manufacturing the brightness-adjustable illuminator of claim 1, comprising:
providing a semiconductor substrate;
processing a vertical LED structure on the semiconductor substrate, wherein the LED structure is comprised of a p-type region, a luminous layer and an n-type region of an LED from the top down;
forming a first insulation film on the p-type region of the LED;
providing a second semiconductor substrate and forming a silicon oxide film on the surface of the second semiconductor substrate;
bonding the first insulation film and the silicon oxide film on the surface of the second semiconductor substrate;
processing a MOSFET structure on the surface of the other side of the second semiconductor substrate that is not bonded, wherein the MOSFET structure is comprised of a source region, a drain region and a gate region located above a groove between the source region and the drain region;
forming a second insulation film on the gate region between the source region and the drain region and etching the second insulation film to form contact holes; and
forming a first conductive film in the contact holes and above the second insulation film and etching the first conductive film to form metal contact, wherein the p-type region of the LED and the source region of the MOSFET are connected via the first conductive film.

6. The method for manufacturing the brightness-adjustable illuminator of claim 5, wherein the semiconductor substrate is made of GaN, GaP, GaAs, InGaAs, InP, or SIC.

7. The method for manufacturing the brightness-adjustable illuminator of claim 5-6, wherein the first and second insulation films are SiO₂ or Si₃N₄ films.

8. The method for manufacturing the brightness-adjustable illuminator of claim 5-6, wherein the first conductive film is made of conductive metallic materials, such as Cu, Al, TiN, Ti, Ta, or TaN.

9. A projection equipment, which uses the chips Integrated by the illuminator of claims 1-4 as a light source for emission image.
